(19) United States
(12) Patent Application Publication
(10) Pub. No.: US 2026/0344494 A1
(43) Pub. Date: Oct. 29, 2026

(54) SEMICONDUCTOR PACKAGE INCLUDING THROUGH-STRUCTURES

(71) Applicant: Samsung Electronics Co., Ltd., Suwon-si (KR)

(72) Inventors: Taejae Park, Suwon-si (KR); Chaein Moon, Suwon-si (KR); Hyeonrae Cho, Suwon-si (KR)

(21) Appl. No.: 19/569,710

(22) Filed: Mar. 17, 2026

(30) Foreign Application Priority Data
Apr. 24, 2025 (KR) 10-2025-0054001

(51) Int. Cl. H10W 72/00; H10W 70/00; H10W 90/00; H10W 90/26; H10W 70/60; H10W 70/68

(52) U.S. Cl. CPC H10W 72/823; H10W 70/099; H10W 90/26; H10W 90/401; H10W 90/732; H10W 70/614; H10W 70/682; H10W 72/877; H10W 90/724

(57) ABSTRACT

A semiconductor package includes a lower interconnection structure including a lower insulating layer and a lower interconnection layer; a lower semiconductor chip mounted on the lower interconnection structure and connected to the lower interconnection layer; a first through-structure disposed around the lower semiconductor chip, on the lower interconnection structure; an upper semiconductor chip on the lower semiconductor chip; a second through-structure disposed around the upper semiconductor chip, on the first through-structure; an encapsulant on the lower interconnection structure; and an upper interconnection structure disposed on the encapsulant and including an upper insulating layer and an upper interconnection layer connected to the upper semiconductor chip. An upper side of the first through-structure and a lower side of the second through-structure face each other. The first through-structure and the second through-structure are connected to each other through the upper side and the lower side of the interconnection structures.

### CROSS-REFERENCE TO RELATED APPLICATIONS

This application claims benefit under 35 USC 119(a) of Korean Patent Application No. 10-2025-0054001 filed on Apr. 24, 2025, in the Korean Intellectual Property Office, the disclosure of which is incorporated herein by reference in its entirety.

### BACKGROUND

The present disclosures relate to a semiconductor package and/or a method of manufacturing the same.

In response to demand for high performance and miniaturization of electronic devices, stacked package technology integrating a plurality of semiconductor packages into a single package has gained attention. Such a stacked package may implement high functionality in a limited region. However, the stack structure may cause problems such as heat accumulation between semiconductor chips. Accordingly, technology development is actively underway to improve the heat dissipation characteristics of stacked packages.

### SUMMARY

An aspect of the present disclosure is to provide a semiconductor package having improved heat dissipation characteristics.

A semiconductor package according to example implementations may comprise: a lower interconnection structure; a chip structure disposed on the lower interconnection structure; a plurality of through-structures disposed around the chip structure, on the lower interconnection structure; an encapsulant covering at least portions of the chip structure and the plurality of through-structures, on the lower interconnection structure; and an upper interconnection structure disposed on the encapsulant, and the lower interconnection structure may comprise: a lower insulating layer; and a lower interconnection layer disposed within the lower insulating layer, the upper interconnection structure may comprise: an upper insulating layer; and an upper interconnection layer disposed within the upper insulating layer, the chip structure may comprise: a lower semiconductor chip disposed on the lower interconnection structure and electrically connected to the lower interconnection layer; and an upper semiconductor chip disposed on the lower semiconductor chip and electrically connected to the upper interconnection layer, and each of the plurality of through-structures may comprise: a first through-structure disposed around the lower semiconductor chip, on the lower interconnection structure; a second through-structure disposed around the upper semiconductor chip, on the first through-structure; and connection members disposed between the first through-structure and the second through-structure, and bonding the first through-structure and the second through-structure.

A semiconductor package according to example implementations may comprise: a lower interconnection structure including a lower insulating layer and lower connection terminals disposed on an upper surface of the lower insulating layer; a lower semiconductor chip disposed on the lower interconnection structure; a first through-structure disposed around the lower semiconductor chip, on the lower interconnection structure; a second through-structure disposed on the first through-structure; a connection member disposed between the first through-structure and the second through-structure and electrically connecting the first through-structure and the second through-structure; an upper interconnection structure disposed on the second through-structure and including an upper insulating layer and upper connection terminals disposed on a lower surface of the upper insulating layer; an upper semiconductor chip disposed between the upper interconnection structure and the lower semiconductor chip; and an encapsulant covering at least a portion of each of the lower semiconductor chip, the upper semiconductor chip, the first through-structure, and the second through-structure, between the lower interconnection structure and the upper interconnection structure, and the lower connection terminals may comprise a first lower connection terminal electrically connected to the first through-structure and a second lower connection terminal electrically connected to the lower semiconductor chip, and the upper connection terminals may comprise a first upper connection terminal electrically connected to the second through-structure and a second upper connection terminal electrically connected to the upper semiconductor chip.

A semiconductor package according to example implementations may comprise: a lower interconnection structure including a lower insulating layer and a lower interconnection layer; a lower semiconductor chip mounted on the lower interconnection structure and electrically connected to the lower interconnection layer; a first through-structure disposed around the lower semiconductor chip, on the lower interconnection structure; an upper semiconductor chip mounted on the lower semiconductor chip; a second through-structure disposed around the upper semiconductor chip, on the first through-structure; an encapsulant encapsulating the lower semiconductor chip, the first through-structure, the upper semiconductor chip and the second through-structure, on the lower interconnection structure; and an upper interconnection structure disposed on the encapsulant and including an upper insulating layer and an upper interconnection layer electrically connected to the upper semiconductor chip, and an upper side of the first through-structure and a lower side of the second through-structure may face each other, and the first through-structure and the second through-structure may be electrically connected to each other through the upper side and the lower side.

A plurality of first through-structures may be disposed on a lower interconnection structure, a plurality of second through-structures may be disposed on an upper interconnection structure, and second through-structures on the upper interconnection structure may be disposed on the plurality of first through-structures, so that a height of a portion in which a chip structure is disposed may be increased. Accordingly, a heat dissipation space may be secured around a chip structure, and a heat dissipation path may be improved. Since the heat dissipation characteristics are improved, a temperature increase of a semiconductor package may be suppressed even upon driving a high-performance device, and the thermal reliability of the semiconductor package may be increased.

Advantages and effects of the present application are not limited to the foregoing content and may be more easily understood in the process of describing specific example implementations of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic cross-sectional view illustrating a semiconductor package according to some example implementations of the present disclosure, FIG. 2 is a vertical plane view along line I-I’ of the semiconductor package of FIGS. 1, and 3 is a partial enlarged view of region “A” of FIG. 1;

FIG. 4 is a cross-sectional view illustrating a semiconductor package according to some example implementations of the present disclosure;

FIG. 5 is a cross-sectional view illustrating a semiconductor package according to some example implementations of the present disclosure;

FIG. 6 is a cross-sectional view illustrating a semiconductor package according to some example implementations of the present disclosure;

FIG. 7 is a cross-sectional view illustrating a semiconductor package according to some example implementations of the present disclosure;

FIG. 8 is a cross-sectional view illustrating a semiconductor package according to some example implementations of the present disclosure; and

FIGS. 9-14 are cross-sectional views schematically illustrating a manufacturing process of a semiconductor package according to some example implementations of the present disclosure.

### DETAILED DESCRIPTION

Hereinafter, example implementations of the present disclosure will be described with reference to the accompanying drawings. Unless otherwise specified, in the present specification, it may be understood that the expressions such as “on,” “above,” “upper,” “below”, “beneath,” “lower,” and “side,” are merely indicated based on drawings, and may actually vary depending on the direction in which the components are disposed.

In order to distinguish various elements, steps and directions from each other, ordinal numbers such as “first,” “second,” “third,” etc. may be used as labels such as specific elements, steps, and directions, terms not described using “first,” “second,” etc. in the specification may still be referred to as “first” or “second” in the claim. In addition, terms referred to as specific ordinal numbers (e.g., “first” in certain claims) may be described as different ordinal numbers (e.g., “second” in specifications or other claims) elsewhere.

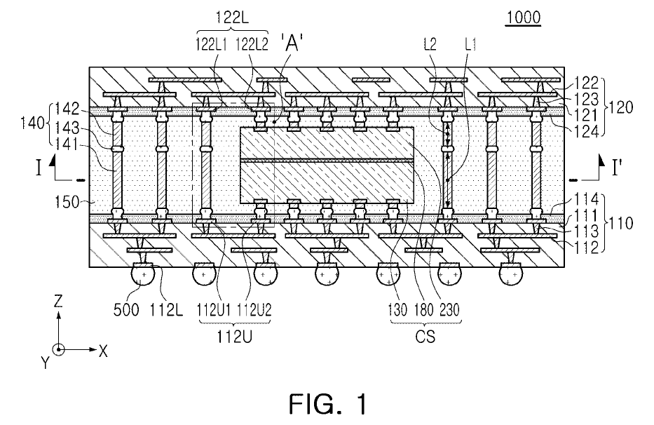

FIG. 1 is a schematic cross-sectional view illustrating a semiconductor package 1000 according to some example implementations of the present disclosure, FIG. 2 is a plan view illustrating a vertical cross-section along line I-I’ of the semiconductor package of FIGS. 1, and 3 is a partial enlarged view of region “A” of FIG. 1.

Referring to FIGS. 1-3, the semiconductor package 1000 of some example implementations may include a lower interconnection structure 110, a chip structure CS, a plurality of through-structures 140, an encapsulant 150, an upper interconnection structure 120, and external connection conductors 500.

The lower interconnection structure 110 is a support substrate on which a lower semiconductor chip 130 is mounted, and may include a lower insulating layer 111, a lower interconnection layer 112, and a lower interconnection via 113. The lower interconnection structure 110 may be a substrate for a semiconductor package, including a printed circuit board (PCB), a ceramic substrate, a glass substrate, and a tape interconnection substrate.

The lower insulating layer 111 may include, for example, a thermosetting resin such as an epoxy resin, a thermoplastic resin such as a polyimide, or prepreg including an inorganic filler and/or glass fiber (Glass Fiber, Glass Cloth or Glass Fabric), ABF, FR-4, or the like.

The lower insulating layer 111 may include a plurality of insulating layers stacked in a vertical direction (e.g., Z-axis direction). For example, the lower insulating layer 111 may include a core layer and a build-up layer stacked on an upper surface and/or a lower surface of the core layer. Depending on the process, boundaries between the plurality of lower insulating layers may not be clearly identified with the naked eye. According to some example implementations, the lower insulating layer 111 may include a photosensitive resin such as a Photoimageable Dielectric (PID).

The lower interconnection layer 112 may be disposed within the lower insulating layer 111. The lower interconnection layer 112 may form an electrical connection path within the lower insulating layer 111. The lower interconnection layer 112 may include, for example, at least one conductive material selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C), or alloys including two or more conductive materials. Each of the lower interconnection layers 112 may be formed of an electrolytically deposited (ED) copper foil, a rolled-annealed (RA) copper foil, ultra-thin copper foils, sputtered copper, copper alloys, and the like.

The lower interconnection layer 112 may include a plurality of pattern layers spaced apart in the vertical direction (e.g., in the Z-axis direction). The plurality of pattern layers may extend in a horizontal direction (e.g., in the X-axis direction or the Y-axis direction) on each vertical level. The lower interconnection layer 112 may include fewer or more pattern layers than those illustrated in the drawing. The plurality of lower interconnection layers 112 may be disposed on different vertical levels.

The lower interconnection layer 112 may include external connection terminals 112L and lower connection terminals 112U. The external connection terminals 112L may be pad portions of a lowermost lower interconnection layer 112, and the lower connection terminals 112U may be pad portions of an uppermost lower interconnection layer 112. The lower interconnection layer 112 and the lower connection terminals 112U may be electrically connected through lower interconnection vias 113.

The lower interconnection layer 112 may include a first lower connection terminal 112U1 electrically connected to the first through-structure 141 and a second lower connection terminal 112U2 electrically connected to the lower semiconductor chip 130.

The lower interconnection layer 112 may perform various functions depending on the design. For example, the lower interconnection layer 112 may include a ground pattern, a power pattern, and a signal pattern.

The lower interconnection via 113 may electrically connect a plurality of lower interconnection layers 112 disposed on different levels within the lower insulating layer 111. The lower interconnection via 113 may include, for example, at least one conductive material selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C), or alloys including two or more conductive materials.

The lower interconnection via 113 may be formed by either completely filling a via hole, which penetrates at least a portion of the lower insulating layer 111, with a conductive material, or by conformally forming a conductive material along a wall of the via hole. According to some example implementations, at least a portion of the lower interconnection via 113 may be formed in a form in which a conductive material is coated along the wall of the via hole, and a space inside the via hole surrounded by the conductive material is filled with an insulating material.

The lower interconnection via 113 may be provided so that a width in a horizontal direction (e.g., X-axis direction or Y-axis direction) of a lower side thereof is less than a width of an upper side thereof. The lower interconnection via 113 may be provided so that a diameter of an upper surface thereof is greater than a diameter of a lower surface thereof. The lower interconnection via 113 may have a width in a horizontal direction (e.g., X-axis direction or Y-axis direction) decreasing in a direction oriented from an upper surface of the lower interconnection structure 110 toward a lower surface, in the vertical direction (e.g., Z-axis direction).

The lower interconnection structure 110 may further include a lower protection layer 114.

The lower protection layer 114 may be formed on an upper surface of the lower insulating layer 111. The lower protection layer 114 may include an opening exposing at least a portion of the lower connection terminals 112U. The lower protection layer 114 may be formed using, for example, a solder resist. In some example implementations, the lower protection layer 114 may further be disposed below the lower interconnection structure 110.

The upper interconnection structure 120 may be disposed on the encapsulant 150. The upper interconnection structure 120 is a support substrate on which an upper semiconductor chip 230 is mounted, and may include an upper insulating layer 121, an upper interconnection layer 122, and an upper interconnection via 123. The upper interconnection structure 120 may be a substrate for a semiconductor package, including a printed circuit board (PCB), a ceramic substrate, a glass substrate, and a tape interconnection substrate.

The upper insulating layer 121 may include, for example, a thermosetting resin such as an epoxy resin, a thermoplastic resin such as a polyimide, or prepreg including an inorganic filler and/or glass fiber (Glass Fiber, Glass Cloth or Glass Fabric), ABF, FR-4, or the like.

The upper insulating layer 121 may include a plurality of insulating layers stacked in the vertical direction (e.g., in the Z-axis direction). For example, the upper insulating layer 121 may include a core layer and a build-up layer stacked on an upper surface and/or a lower surface of the core layer. Depending on the process, boundaries between the plurality of upper insulating layers may not be clearly identified. According to some example implementations, the upper insulating layer 121 may include a photosensitive resin such as a Photoimageable Dielectric (PID).

The upper interconnection layer 122 may be disposed within the upper insulating layer 121. The upper interconnection layer 122 may form an electrical connection path within the upper insulating layer 121.

The upper interconnection layer 122 may include, for example, at least one conductive material from copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C), or alloys including two or more conductive materials. Each of the upper interconnection layers 122 may be formed of an electrolytically deposited (ED) copper foil, a rolled-annealed (RA) copper foil, ultra-thin copper foils, sputtered copper, copper alloys, or the like.

The upper interconnection layer 122 may include a plurality of pattern layers spaced apart from each other in the vertical direction (e.g., in the Z-axis direction). The plurality of pattern layers may extend in the horizontal direction (e.g., in the X-axis direction or the Y-axis direction) on each vertical level. The upper interconnection layer 122 may include fewer or more pattern layers than those illustrated in the drawing. The plurality of upper interconnection layers 122 may be disposed on different levels.

The plurality of upper interconnection layers 122 may include upper connection terminals 122L. The upper connection terminals 122L may be pad portions of a lowermost upper interconnection layer 122. The upper interconnection layer 122 and the upper connection terminals 122L may be electrically connected through upper interconnection vias 123.

The upper interconnection layer 122 may include a first upper connection terminal 122L1 electrically connected to a second through-structure 142 and a second upper connection terminal 122L2 electrically connected to the upper semiconductor chip 230.

The upper interconnection layer 122 may perform various functions depending on the design. For example, the upper interconnection layer 122 may include a ground pattern, a power pattern, and a signal pattern.

The upper interconnection via 123 may electrically connect a plurality of upper interconnection layers 122 disposed on different levels within the upper insulating layer 121. The upper interconnection via 123 may include, for example, at least one conductive material from copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or alloys including two or more conductive materials.

The upper interconnection via 123 may be formed by either completely filling a via hole, which penetrates at least a portion of the lower insulating layer 111, with a conductive material, or by conformally forming a conductive material along a wall of the via hole. According to some example implementations, at least a portion of the upper interconnection via 123 may be formed may be formed in a form in which a conductive material is coated along the wall of the via hole, and a space inside the via hole surrounded by the conductive material is filled with an insulating material.

The upper interconnection via 123 may be provided so that a width of a lower side thereof in the horizontal direction (e.g., X-axis direction or Y-axis direction) is greater than a width of an upper side thereof. The upper interconnection via 123 may be provided so that a diameter of an upper surface thereof is less than a diameter of a lower surface thereof. The upper interconnection via 123 may have a width in a horizontal direction (e.g., X-axis direction or Y-axis direction) increasing in a direction from an upper surface of the upper interconnection structure 120 toward a lower surface, in a vertical direction (e.g., Z-axis direction).

The upper interconnection structure 120 may further include an upper protection layer 124.

The upper protection layer 124 may be formed on a lower surface of the upper insulating layer 121. The upper protection layer 124 may include an opening exposing at least a portion of the upper connection terminals 122L. The upper protection layer 124 may be formed using, for example, a solder resist.

The chip structure CS may be disposed on the lower interconnection structure 110. The chip structure CS may include a lower semiconductor chip 130, an inter-chip adhesive layer 180, and an upper semiconductor chip 230.

The lower semiconductor chip 130 may be disposed on the lower interconnection structure 110 and may be electrically connected to the lower interconnection layer 112. The lower semiconductor chip 130 may be electrically connected to the first through-structure 141 through the lower connection terminals 112U, the lower interconnection vias 113 and the lower interconnection layer 112.

The lower semiconductor chip 130 may be disposed so that an active surface on which connection pads 130P are disposed faces the lower interconnection structure 110. The lower semiconductor chip 130 may be provided as a plurality of semiconductor chips arranged in the vertical direction (e.g., in the Z-axis direction) or the horizontal direction (e.g., in the X-axis direction or the Y-axis direction). The lower semiconductor chip 130 may be electrically connected to the second lower connection terminals 112U2 through lower conductive bumps 135.

The lower conductive bumps 135 may include a pillar portion 133 and a solder portion 134. The pillar portion 133 may include copper (Cu) or alloys of copper (Cu), and the solder portion 134 may include a low melting point metal, for example, tin (Sn) or alloys including tin (Sn) (Sn-Ag-Cu). According to some example implementations, the lower conductive bumps 135 may include only the pillar portion 133 or only the solder portion 134. The lower conductive bumps 135 may be disposed between the lower semiconductor chip 130 and the second lower connection terminal 112U2.

Each of the lower conductive bumps 135 may be surrounded by the encapsulant 150, and in this case, a molded underfill (MUF) structure may be formed in which the encapsulant 150 fills a periphery of the lower conductive bumps 135. The lower conductive bumps 135 may be surrounded by an underfill portion. The underfill portion may have a capillary underfill (CUF) structure. A lower interposed portion 150INL may be interposed between the lower semiconductor chip 130 and the lower interconnection structure 110 and may be in contact with the upper surface of the lower interconnection structure 110 and a lower surface of the lower semiconductor chip 130. A sidewall of the lower interposed portion 150INL may be in contact with a sidewall of the lower conductive bumps 135.

The lower semiconductor chip 130 may be a bare semiconductor chip in which a separate bump or a separate interconnection layer is not formed, but the present disclosure is not limited thereto, and the lower semiconductor chip 130 may be a packaged type semiconductor chip. The lower semiconductor chip 130 may include a semiconductor wafer comprised of a semiconductor element such as silicon or germanium, or a compound semiconductor such as silicon carbide (SiC), gallium arsenide (GaAs), indium arsenide (InAs) and indium phosphide (InP), and an integrated circuit (IC) formed on the semiconductor wafer.

The lower semiconductor chip 130 may be a logic chip including a central processor (CPU), a graphics processor (GPU), a field programmable gate array (FPGA), an application processor (AP), a digital signal processor, an encryption processor, a microprocessor, a microcontroller, an analog-to-digital converter, and an application-specific IC (ASIC). According to some example implementations, the lower semiconductor chip 130 may further include a memory chip including a volatile memory such as a dynamic RAM (DRAM), a static RAM (SRAM), and a nonvolatile memory such as a phase change RAM (PRAM), a magnetic RAM (MRAM), a resistive RAM (RRAM) and a flash memory.

The upper semiconductor chip 230 may be disposed on the lower semiconductor chip 130 and may be electrically connected to the upper interconnection layer 122. The upper semiconductor chip 230 may be electrically connected to the second through-structure 142 through the upper connection terminals 122L, the upper interconnection vias 123 and the upper interconnection layer 122. The lower semiconductor chip 130 and the upper semiconductor chip 230 may be electrically connected to each other.

The upper semiconductor chip 230 may be disposed so that the active surface on which connection pads 230P are disposed faces the upper interconnection structure 120. The upper semiconductor chip 230 may be disposed between the upper interconnection structure 120 and the lower semiconductor chip 130. The upper semiconductor chip 230 may be provided as a plurality of semiconductor chips arranged in the vertical direction (e.g., in the Z-axis direction) or the horizontal direction (e.g., in the X-axis direction or the Y-axis direction). The upper semiconductor chip 230 may be electrically connected to the second upper connection terminals 122L2 through upper conductive bumps 235. In a direction perpendicular to the upper surface of the lower interconnection structure 110 (e.g., in the Z-axis direction), a thickness of the upper semiconductor chip 230 may be less than a thickness of the lower semiconductor chip 130.

The upper conductive bumps 235 may include a pillar portion 233 and a solder portion 234. The pillar portion 233 may include copper (Cu) or alloys of copper (Cu), and the solder portion 234 may include a low-melting point metal, for example, tin (Sn) or alloys including tin (Sn) (Sn-Ag-Cu). According to some example implementations, the upper conductive bumps 235 may include only the pillar portion 233 or only the solder portion 234. The upper conductive bumps 235 may be disposed between the upper semiconductor chip 230 and the second upper connection terminal 122L2.

Each of the upper conductive bumps 235 may be surrounded by the encapsulant 150, and in this case, a molded underfill (MUF) structure may be formed in which the encapsulant 150 fills the periphery of the upper conductive bumps 235. The upper conductive bumps 235 may be surrounded by an underfill portion. The underfill portion may have a capillary underfill (CUF) structure. An upper interposed portion 150INU may be interposed between the upper semiconductor chip 230 and the upper interconnection structure 120 and may thus be in contact with a lower surface of the upper interconnection structure 120 and an upper surface of the upper semiconductor chip 230. A sidewall of the upper interposed portion 150INU may be in contact with a sidewall of the upper conductive bumps 235.

The upper semiconductor chip 230 may be a bare semiconductor chip in which a separate bump or a separate interconnection layer is not formed, but the present disclosure is not limited thereto, and the upper semiconductor chip 230 may be a packaged type semiconductor chip. The upper semiconductor chip 230 may include a semiconductor wafer comprised of a semiconductor element such as silicon or germanium, or a compound semiconductor such as silicon carbide (SiC), gallium arsenide (GaAs), indium arsenide (InAs) and indium phosphide (InP), and an integrated circuit (IC) formed on the semiconductor wafer.

The upper semiconductor chip 230 may be a logic chip including a central processor (CPU), a graphics processor (GPU), a field programmable gate array (FPGA), an application processor (AP), a digital signal processor, an encryption processor, a microprocessor, a microcontroller, an analog-to-digital converter and an application-specific IC (ASIC). According to some example implementations, the upper semiconductor chip 230 may further include a memory chip including a volatile memory such as a dynamic RAM (DRAM), a static RAM (SRAM), and a nonvolatile memory such as a phase change RAM (PRAM), a magnetic RAM (MRAM), a resistive RAM (RRAM) and a flash memory.

The inter-chip adhesive layer 180 may bond and couple the lower semiconductor chip 130 and the upper semiconductor chip 230 to each other. An upper surface of the lower semiconductor chip 130 may be bonded to a lower surface of the inter-chip adhesive layer 180, and a lower surface of the upper semiconductor chip 230 may be bonded to an upper surface of the inter-chip adhesive layer 180. The inter-chip adhesive layer 180 may include materials that may be bonded to each other, for example, at least one of silicon oxide (SiO) or a compound thereof. In some example implementations, the inter-chip adhesive layer 180 may include a thermosetting resin or an ultraviolet-curable resin in a film form. For example, the inter-chip adhesive layer 180 may include a resin film such as a die attach film (DAF).

A plurality of through-structures 140 may extend into at least a portion of the encapsulant 150 between the lower interconnection structure 110 and the upper interconnection structure 120 and may extend in a direction perpendicular to the upper surface of the lower interconnection structure 110 (e.g., in the Z-axis direction). The plurality of through-structures 140 may extend into the encapsulant 150 and may be electrically connected to the upper interconnection layer 122 through the upper interconnection via 123. The plurality of through-structures 140 may be disposed around the chip structure CS.

In the semiconductor package 1000, the plurality of through-structures 140 between the lower interconnection structure 110 and the upper interconnection structure 120 may be formed, so that a structure in which the plurality of through-structures 140 surround the chip structure CS may be provided. The structure in which the plurality of through-structures 140 surround the chip structure CS may have the chip structure CS disposed therein and may contribute to increasing a thickness of the encapsulant 150 in the vertical direction (e.g., in the Z-axis direction) in a region surrounding the chip structure CS. The plurality of through-structures 140 may not only support the upper interconnection structure 120 around the chip structure CS, but may also sufficiently secure a region in which the encapsulant 150 may be disposed.

When the thickness of the encapsulant 150 in the vertical direction (e.g., in the Z-axis direction) increases, a plurality of heat transfer paths for heat generated in the chip structure CS to the outside may be formed. The heat generated in the chip structure CS may be efficiently diffused to the outside through the heat transfer path. The heat generated in the chip structure CS may be prevented from being concentrated in one position, and thus, for example, even if heavily heated chips are included in the chip structure CS, an excessive temperature increase of the semiconductor package 1000 may be suppressed. The thermal stability of the semiconductor package 1000 may be secured and a continuous operation of a high-performance semiconductor chip may be achieved. For example, the semiconductor package 1000 may be advantageously utilized in fields requiring high performance or applied to a high-temperature environment.

The thickness of the encapsulant 150 in the vertical direction (e.g., Z-axis direction) may be increased, but a thickness of the semiconductor package 1000 in the vertical direction (e.g., Z-axis direction) may be reduced. By means of an arrangement of the plurality of through-structures 140 and a design in which the lower semiconductor chip 130 and the upper semiconductor chip 230 overlap each other, the thickness of the encapsulant 150 in the vertical direction (e.g., Z-axis direction) may be increased, but the thickness of the semiconductor package 1000 in the vertical direction (e.g., Z-axis direction) may be reduced. Accordingly, a more compact package design may be achieved, which may be very advantageous in the field of small electronic devices such as portable devices or wearable devices.

In this manner, since the semiconductor package 1000 may be implemented in a smaller size even with the same performance, high integration may also be achieved. Since the thickness of the semiconductor package 1000 in the vertical direction (e.g., Z-axis direction) is reduced, the integration efficiency on a system level may be improved. Accordingly, the semiconductor package 1000 of the present disclosure may provide excellent results in terms of performance, thermal characteristics, miniaturization, and integration.

The plurality of through-structures 140 may include a plurality of first through-structures 141 surrounding the lower semiconductor chip 130, a plurality of second through-structures 142 surrounding the upper semiconductor chip 230, and connection members 143 connecting each of the plurality of first through-structures 141 and each of the plurality of second through-structures 142.

The plurality of first through-structures 141 may be disposed around the lower semiconductor chip 130, on the lower interconnection structure 110. The plurality of first through-structures 141 may extend into at least a portion of the encapsulant 150 on the lower interconnection structure 110 and may electrically connect the lower interconnection structure 110 and the upper interconnection structure 120. The plurality of first through-structures 141 may be disposed between the lower interconnection structure 110 and the upper interconnection structure 120. The plurality of first through-structures 141 may be disposed around the lower semiconductor chip 130 on a plane. For example, the plurality of first through-structures 141 may be disposed on both sides of the lower semiconductor chip 130. However, the present disclosure is not limited thereto, and the plurality of first through-structures 141 may be disposed to surround the lower semiconductor chip 130 on a plane. The plurality of first through-structures 141 may be spaced apart from each other by a predetermined interval. However, the present disclosure is not limited thereto. In addition, a greater number of first through-structures 141 than that illustrated in FIG. 2 may be disposed on the lower interconnection structure 110. The first through-structures 141 may be electrically connected to the lower interconnection layer 112. The plurality of first through-structures 141 may be electrically connected to the lower semiconductor chip 130 through the plurality of lower interconnection vias 113 and the plurality of lower interconnection layers 112.

A structure in which the plurality of first through-structures 141 are disposed may have a rectangular shape on a plane but is not limited thereto. Each of the plurality of first through-structures 141 may have a cylindrical shape, but is not limited thereto, and may have a rectangular prism shape. Each of the plurality of first through-structures 141 may have a pillar shape extending in the vertical direction (e.g., in the Z-axis direction).

Each of the plurality of first through-structures 141 may include copper (Cu), nickel (Ni), titanium (Ti), lead (Pb), aluminum (Al), silver (Ag), gold (Au), platinum (Pt), or alloys thereof. In some example implementations, each of the plurality of first through-structures 141 may include copper (Cu).

Each of the plurality of first through-structures 141 may be electrically connected to the first lower connection terminals 112U1 through a first solder portion 141S disposed on a lower side of the first through-structure 141. The first through-structure 141 may be electrically connected to the lower interconnection layer 112 through the first lower connection terminals 112U1. The first through-structure 141 may be electrically connected to the lower interconnection layer 112 through the first solder portion 141S and the first lower connection terminal 112U1. Each of the plurality of first through-structures 141 may be formed to contact the first lower connection terminals 112U1 without the first solder portion 141S. In this case, the plurality of first through-structures 141 may be formed of the same material as the first lower connection terminals 112U1. The plurality of first through-structures 141 may have a structure in which a width thereof in the horizontal direction (e.g., in the X-axis direction or the Y-axis direction) decreases in a direction oriented toward the upper surface of the lower interconnection structure 110.

The first through-structure 141 may be electrically connected to the lower semiconductor chip 130 through the lower interconnection layer 112. An upper surface of the first through-structure 141 may be in contact with a lower surface of the connection member 143. The first through-structure 141 may be electrically connected to the second through-structure 142 through the connection member 143.

The plurality of second through-structures 142 may be disposed around the upper semiconductor chip 230, on the first through-structure 141. The plurality of second through-structures 142 extend into at least a portion of the encapsulant 150, on the plurality of first through-structures 141, and may electrically connect the lower interconnection structure 110 and the upper interconnection structure 120. The plurality of second through-structures 142 may be disposed between the lower interconnection structure 110 and the upper interconnection structure 120. The plurality of second through-structures 142 may be disposed around the upper semiconductor chip 230 on a plane. For example, the plurality of second through-structures 142 may be disposed on both sides of the upper semiconductor chip 230. However, the present disclosure is not limited thereto, and the plurality of second through-structures 142 may be disposed to surround the upper semiconductor chip 230 on a plane. The plurality of second through-structures 142 may be spaced apart from each other by a predetermined interval. However, the present disclosure is not limited thereto. The second through-structures 142 may be electrically connected to the upper interconnection layer 122. The plurality of second through-structures 142 may be electrically connected to the upper semiconductor chip 230 through the plurality of upper interconnection vias 123 and the plurality of upper interconnection layers 122.

A structure in which the plurality of second through-structures 142 are arranged may have a rectangular shape on a plane, but the present disclosure is not limited thereto. Each of the plurality of second through-structures 142 may have a cylindrical shape but is not limited thereto and may have a rectangular prism shape. Each of the plurality of second through-structures 142 may have a pillar shape extending in the vertical direction (e.g., in the Z-axis direction).

Each of the plurality of second through-structures 142 may include copper (Cu), nickel (Ni), titanium (Ti), lead (Pb), aluminum (Al), silver (Ag), gold (Au), platinum (Pt), or alloys thereof. In some example implementations, each of the plurality of second through-structures 142 may include copper (Cu).

Each of the plurality of second through-structures 142 may be electrically connected to the first upper connection terminals 122L1 through a second solder portion 142S disposed on an upper side of the second through-structure 142. The second through-structure 142 may be electrically connected to the upper interconnection layer 122 through the first upper connection terminals 122L1. The second through-structure 142 may be electrically connected to the upper interconnection layer 122 through the second solder portion 142S and the first upper connection terminal 122L1. Each of the plurality of second through-structures 142 may be formed to contact the first upper connection terminals 122L1 without the second solder portion 142S. In this case, the plurality of second through-structures 142 may be formed of the same material as that of the first upper connection terminals 122L1. The plurality of second through-structures 142 may have a structure in which a width thereof in the horizontal direction (e.g., the X-axis direction or the Y-axis direction) decreases in a direction oriented toward the lower surface of the upper interconnection structure 120.

The second through-structure 142 may be electrically connected to the upper semiconductor chip 230 through the upper interconnection layer 122. A lower surface of the second through-structure 142 may be in contact with an upper surface of the connection member 143. The second through-structure 142 may be electrically connected to the first through-structure 141 through the connection member 143.

In a horizontal direction (e.g., X-axis direction or Y-axis direction) parallel to the upper surface of the lower interconnection structure 110, a width 141W of the lower side of the first through-structure 141 and a width of an upper side of the first through-structure 141 may be substantially the same, a width 142W of a lower side of the second through-structure 142 and a width of the upper side of the second through-structure 142 may be substantially the same, and a width 141W of the upper side of the first through-structure 141 and the width 142W of the lower side of the second through-structure 142 may be substantially the same. However, the present disclosure is not limited thereto.

A plurality of connection members 143 may be disposed between the first through-structure 141 and the second through-structure 142 to connect the first through-structure 141 and the second through-structure 142. Each of the plurality of connection members 143 may be disposed between respective first through-structures of the plurality of first through-structures 141 and respective second through-structures of the plurality of second through-structures 142. The connection member 143 may be disposed between the first through-structure 141 and the second through-structure 142. The lower surface of the connection member 143 may contact the upper surface of the first through-structure 141, and the upper surface of the connection member 143 may be in contact with the lower surface of the second through-structure 142. The plurality of connection members 143 may include a low melting point metal, for example, tin (Sn) or alloys including tin (Sn).

Each of the plurality of first through-structures 141 may be electrically connected to a respective second through-structure of the plurality of second through-structures 142 through the connection member 143 disposed on the upper side of the first through-structure 141. The first through-structure 141 may be electrically connected to the upper interconnection layer 122 through the connection member 143 and the second through-structure 142.

Each of the plurality of second through-structures 142 may be electrically connected to a respective first through-structure of the plurality of first through-structures 141 through the connection member 143 disposed on the lower side of the second through-structure 142. The second through-structure 142 may be electrically connected to the lower interconnection layer 112 through the connection member 143 and the first through-structure 141.

The connection member 143 may separate the upper side of the first through-structure 141 and the lower side of the second through-structure 142 in the vertical direction (e.g., in the Z-axis direction). The upper side of the first through-structure 141 may be in contact with a lower side of the connection member 143. The lower side of the second through-structure 142 may be in contact with an upper side of the connection member 143. The connection member 143 may be disposed between the first through-structure 141 and the second through-structure 142, so that the upper side of the first through-structure 141 and the lower side of the second through-structure 142 may be separated in a vertical direction (e.g., in the Z-axis direction). The connection member 143 may be electrically connected to the first through-structure 141. The connection member 143 may be electrically connected to the second through-structure 142. The first through-structure 141 and the second through-structure 142 may be electrically connected through the connection member 143.

The plurality of first through-structures 141 may have a first length L1 in the vertical direction (e.g., in the Z-axis direction). The plurality of second through-structures 142 may have a second length L2 in the vertical direction (e.g., in the Z-axis direction). The first length L1 may be greater than the second length L2. The first length L1 may be greater than the thickness of the lower semiconductor chip 130 in the vertical direction (e.g., in the Z-axis direction). The second length L2 may be less than the thickness of the upper semiconductor chip 230 in a vertical direction (e.g., in the Z-axis direction).

The width 141W of the upper side of the first through-structure 141 and the width 142W of the lower side of the second through-structure 142 may be substantially the same. For example, in the horizontal direction (e.g., X-axis direction or Y-axis direction) parallel to the upper surface of the lower interconnection structure 110, the width 141W of the upper side of the first through-structure 141 and the width 142W of the lower side of the second through-structure 142 may be substantially the same. A width 143W of the connection member 143 may be greater than the width 141W of the upper side of the first through-structure 141. The width 143W of the connection member 143 may be greater than the width 142W of the lower side of the second through-structure 142.

The second length L2 of the plurality of second through-structures 142 may be set to be less than the first length L1 of the plurality of first through-structures 141, thereby reducing an overall weight of the second through-structures 142 formed on the upper interconnection structure 120. For example, when the second through-structures 142 are stacked and disposed on the first through-structures 141, a load burden thereof may be reduced. When the second through-structures 142 are stacked and disposed on the first through-structures 141, a structure in which the second length L2 is less than the first length L1 may prevent deformation or tilting of the first and second through-structures 141 and 142. Accordingly, the manufacturing reliability of the semiconductor package 1000 may be improved.

For example, when the second through-structure 142 in which the second length L2 is less than the first length L1 is adopted, the load of the plurality of second through-structures 142 bonded through the second solder portion 142S may be alleviated, and the bonding strength with the upper interconnection structure 120 may be stably maintained. As the adhesive reliability is secured, the durability of the semiconductor package 1000 may be maintained in a high temperature and high humidity environment.

The encapsulant 150 may encapsulate at least a portion of each of the lower semiconductor chip 130, the inter-chip adhesive layer 180, the upper semiconductor chip 230, the first through-structure 141 and the second through-structure 142 on the upper surface of the lower interconnection structure 110. The encapsulant 150 may cover side surfaces of each of the plurality of first and second through-structures 141 and 142. The encapsulant 150 may cover at least a portion of the chip structure CS and the plurality of through-structures 140 on the lower interconnection structure 110.

The encapsulant 150 may include, for example, a thermosetting resin such as an epoxy resin, a thermoplastic resin such as a polyimide, or prepreg, ABF, FR-4, BT and an Epoxy Molding Compound (EMC), in which an inorganic filler is impregnated into these resins.

The encapsulant 150 may include a lower interposed portion 150INL interposed between the lower semiconductor chip 130 and the lower interconnection structure 110, and an upper interposed portion 150INU interposed between the upper semiconductor chip 230 and the upper interconnection structure 120.

For convenience of explanation, the lower interposed portion 150INL and the upper interposed portion 150INU of the encapsulant 150 are described separately, but the lower interposed portion 150INL and the upper interposed portion 150INU of the encapsulant 150 may have an integral structure connected to the encapsulant 150 without a boundary. The lower interposed portion 150INL and the upper interposed portion 150INU may include the same material.

The lower interposed portion 150INL may be interposed between the lower semiconductor chip 130 and the lower interconnection structure 110 and may be in contact with the upper surface of the lower interconnection structure 110 and the lower surface of the lower semiconductor chip 130.

The upper interposer 150INU may be interposed between the upper semiconductor chip 230 and the upper interconnection structure 120 and may be in contact with the lower surface of the upper interconnection structure 120 and the upper surface of the upper semiconductor chip 230.

Sidewalls of the lower and upper interposers 150INL and 150INU may be in contact with sidewalls of the lower and upper conductive bumps 135 and 235.

The external connection conductors 500 may be disposed on a lower surface of the lower interconnection structure 110. The external connection conductors 500 may be electrically connected to the lower semiconductor chip 130 and the first through-structure 141 through the lower interconnection layer 112. The semiconductor package 1000 may be connected to an external device such as a module substrate or a system board through the external connection conductors 500. For example, the external connecting conductors 500 may include a low melting point metal, such as tin (Sn), or a tin-silver-copper (Sn-Ag-Cu) alloy or a tin-aluminum-copper (Sn-Al-Cu) alloy including tin (Sn).

According to some example implementations, the external connecting conductors 500 may have a form in which a pillar (or underbump metal) and a ball are combined. The pillar may include copper (Cu) or alloys of copper (Cu), and the ball may include a solder ball. According to some example implementations, the lower insulating layer 111 may include a resist layer protecting the external connecting conductors 500 from external physical and chemical damage.

Accordingly, the plurality of through-structures 140 may be formed around the chip structure CS, thereby securing a vertical thickness of the encapsulant 150 and increasing a heat dissipation path. Accordingly, heat generated from a chip may be effectively dispersed to improve thermal stability. Additionally, the thickness of the entire semiconductor package 1000 in the vertical direction (e.g., Z-axis direction) may be maintained to be thin, so that miniaturization may be advantageous. In addition, since the semiconductor package 1000 may be implemented in a smaller area, this may also be advantageous for high integration of the system.

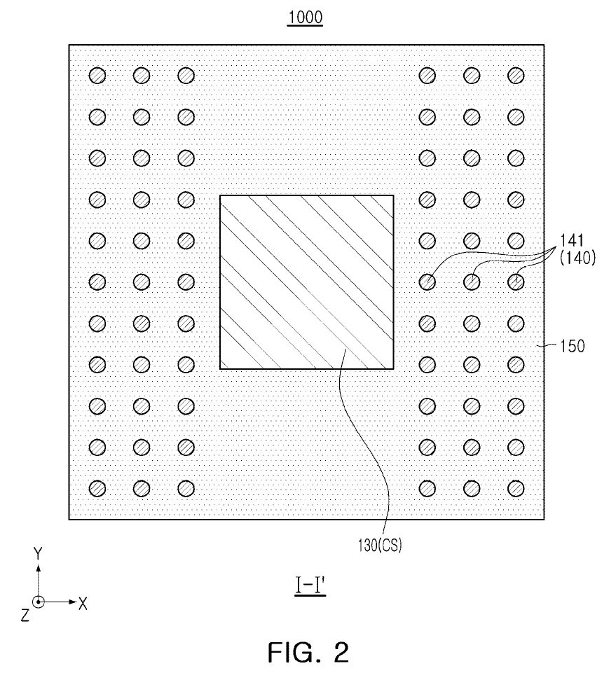

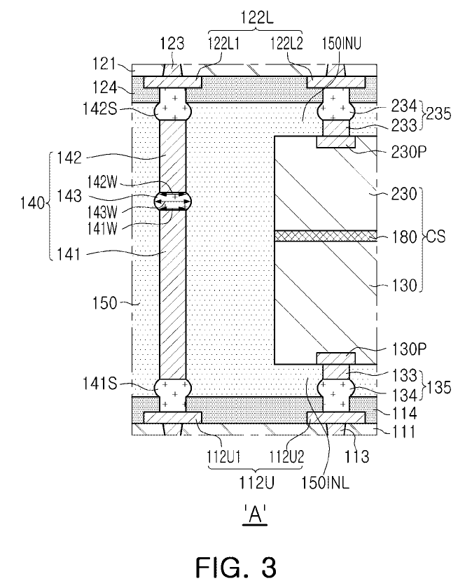

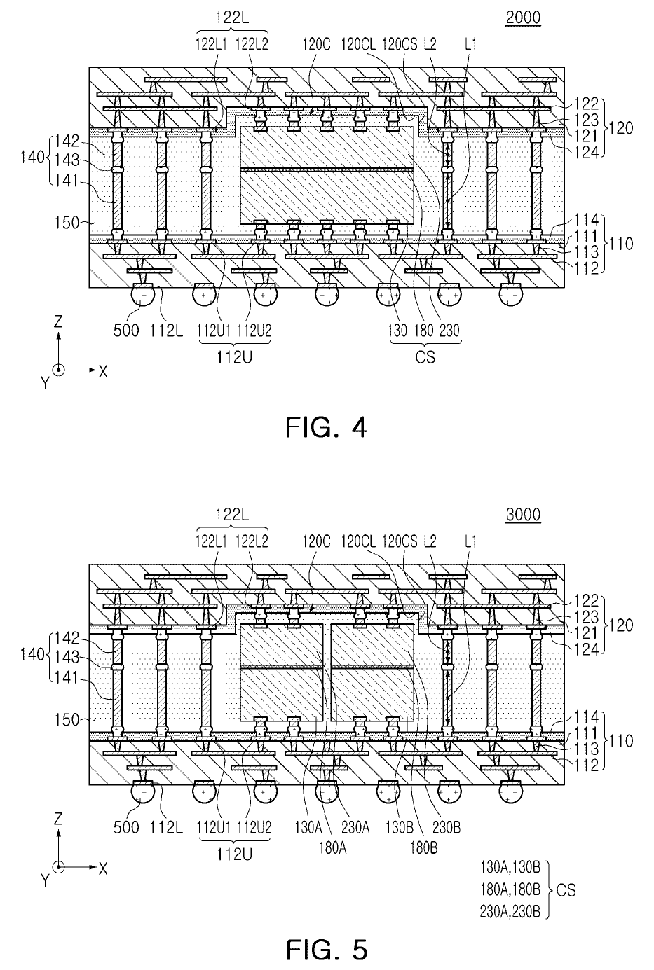

FIG. 4 is a cross-sectional view illustrating a semiconductor package According to some example implementations of the present disclosure.

Referring to FIG. 4, a semiconductor package 2000 of some example implementations may have the features identical to or similar to those described with reference to FIGS. 1-3, except that the semiconductor package 2000 has a cavity 120C in a central portion of the lower surface of the upper interconnection structure 120. Accordingly, the description of the semiconductor package 1000 illustrated in FIGS. 1-3 may be combined with the description of the semiconductor package 2000 according to these example implementations, unless otherwise specifically stated.

The upper interconnection structure 120 may have a cavity 120C in the central portion of the lower surface of the upper interconnection structure 120.

The cavity 120C may be formed in a portion overlapping a portion of the upper insulating layer 121 in which the upper semiconductor chip 230 is mounted. A level of the lower surface of the upper insulating layer 121 in the portion in which the cavity 120C is formed may be higher than a level of the lower surface of the upper insulating layer 121 around the cavity 120C. With reference to the upper surface of the lower interconnection structure 110, in the vertical direction (e.g., Z-axis direction), a level on which the first lower connection terminal 112U1 is disposed may be substantially the same as a level on which the second lower connection terminal 112U2 is disposed.

The upper semiconductor chip 230 may be mounted in the cavity 120C. A level of the second upper connection terminal 122L2 disposed on the cavity 120C may be higher than a level of the first upper connection terminal 122L1 around the cavity 120C. With reference to the upper surface of the lower interconnection structure 110, in the vertical direction (e.g., in the Z-axis direction), a level on which the first upper connection terminal 122L1 is disposed may be lower than a level on which the second upper connection terminal 122L2 is disposed.

The upper protection layer 124 may be formed along a lower surface of the upper insulation layer 121. The upper protection layer 124 may be formed along the cavity 120C of the upper insulation layer 121. The upper protection layer 124 may be formed on a side surface 120CS of the cavity 120C. The upper protection layer 124 may be formed on a lower surface 120CL of the cavity 120C. The upper protection layer 124 may be formed conformally along the lower surface of the upper insulation layer 121. The side surface 120CS of the cavity 120C may overlap a portion of a side surface of the upper semiconductor chip 230 in the horizontal direction (e.g., X-axis direction or Y-axis direction). The side surface 120CS of the cavity 120C may surround the upper semiconductor chip 230.

A portion of the upper semiconductor chip 230 may be disposed to overlap the cavity 120C of the upper interconnection structure 120, thereby effectively reducing a thickness of the semiconductor package 2000 in the vertical direction (e.g., Z-axis direction). This enables the mounting of the semiconductor package 2000 even in a limited space, thereby realizing high integration. This may be particularly advantageous in application environments with large space constraints, such as mobile devices or wearable devices. Reducing the thickness of the semiconductor package 2000 may also contribute to miniaturization of an entire product including the semiconductor package 2000.

The thickness of the semiconductor package 2000 in the vertical direction (e.g., Z-axis direction) may be reduced, but a space of the upper semiconductor chip 230 and the lower semiconductor chip 130 in the horizontal direction (e.g., X-axis direction or Y-axis direction) may be maintained to be wide. The heat dissipation performance may be improved by sufficiently securing the heat dissipation path within the semiconductor package 2000. For example, stable operation and performance may be maintained even in the semiconductor package 2000 including a heavily heated semiconductor chip. As a result, the reliability of the semiconductor package 2000 may be improved, and the lifespan of the semiconductor package 2000 may also be improved.

FIG. 5 is a cross-sectional view illustrating a semiconductor package According to some example implementations of the present disclosure.

Referring to FIG. 5, a semiconductor package 3000 of some example implementations may have features identical to or similar to those described with reference to FIGS. 1-4, except that the semiconductor package 3000 includes a plurality of stacked semiconductor chips 130A, 130B, 230A and 230B. The description of the semiconductor package 2000 illustrated in FIGS. 1-4 may be combined with the description of the semiconductor package 3000 according to these example implementations, unless otherwise specifically stated.

The semiconductor package 3000 may include a chip structure CS in which a plurality of semiconductor chips 130A, 130B, 230A and 230B are stacked between the upper surface of the lower interconnection structure 110 and the lower surface of the upper interconnection structure 120.

The chip structure CS is exemplified as including four semiconductor chips 130A, 130B, 230A and 230B stacked two by two in a direction (e.g., in the Z-axis direction), perpendicular to the upper surface of the lower interconnection structure 110, but the present disclosure is not limited thereto. For example, the chip structure CS may include a different number (e.g., 8 or 16) of semiconductor chips.

A lower surface of the first lower semiconductor chip 130A and a lower surface of the second lower semiconductor chip 130B may be active surfaces. An upper surface of the first upper semiconductor chip 230A and an upper surface of the second upper semiconductor chip 230B may be active surfaces. For example, connection pads 130P (see FIG. 3) may be disposed on the lower surface of the first lower semiconductor chip 130A and the lower surface of the second lower semiconductor chip 130B. For example, connection pads 230P (see FIG. 3) may be disposed on the upper surface of the first upper semiconductor chip 230A and the upper surface of the second upper semiconductor chip 230B.

In the stacking process, a first inter-chip adhesive layer 180A may be attached between the first lower semiconductor chip 130A and the first upper semiconductor chip 230A with an area equal to a chip area. A second inter-chip adhesive layer 180B may be attached between the second lower semiconductor chip 130B and the second upper semiconductor chip 230B with an area equal to the chip area.

The first and second lower semiconductor chips 130A and 130B and the first and second upper semiconductor chips 230A and 230B may be one of chiplets of a logic chip including a central processor (CPU), a graphics processor (GPU), a field programmable gate array (FPGA), an application processor (AP), a digital signal processor, an encryption processor, a microprocessor, a microcontroller, an analog-to-digital converter and an application-specific IC (ASIC). According to some example implementations, the first and second lower semiconductor chips 130A and 130B and the first and second upper semiconductor chips 230A and 230B may be one of the chiplets of a memory chip including a volatile memory such as a dynamic RAM (DRAM), a static RAM (SRAM), and a nonvolatile memory such as a phase change RAM (PRAM), a magnetic RAM (MRAM), a resistive RAM (RRAM), and a flash memory.

Here, ‘chiplet’ may refer to a plurality of small semiconductor chips used to configure one system and may refer to a modular semiconductor device each designed to perform a specific function.

The semiconductor package 3000 according to some example implementations may improve an overall heat dissipation performance by sufficiently securing a heat dissipation path within the semiconductor package 3000. This may denote that effective heat management may be performed even in a structure including heavily heated chiplets. The semiconductor package 3000 may maintain stable operation even in a high temperature environment. By suppressing the temperature increase due to heat accumulation, the instability of operation or performance degradation due to overheating of the chiplet may be prevented. Accordingly, the overall reliability of the semiconductor package 3000 may be improved, and the long-term service lifespan may also be increased.

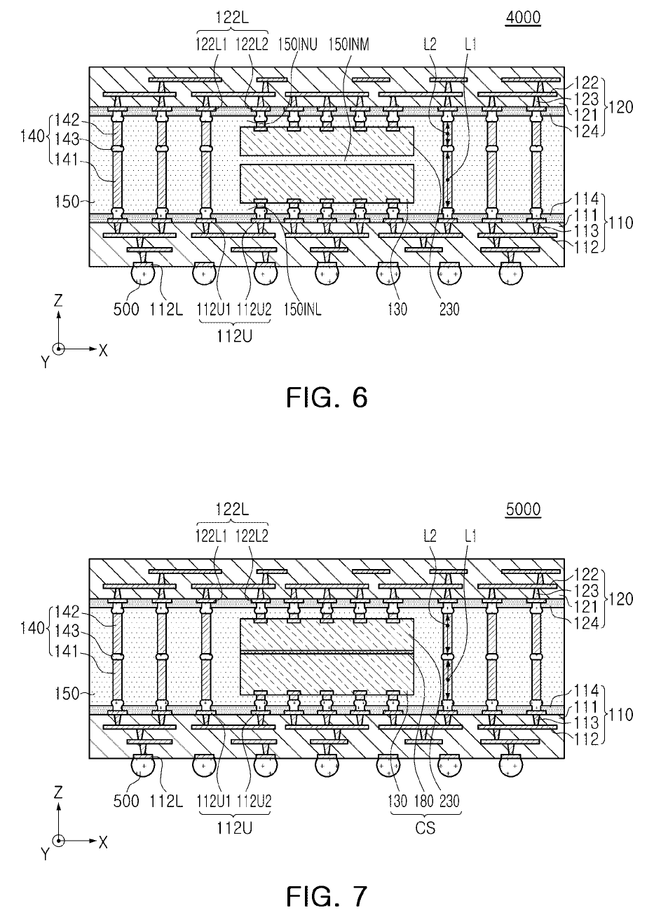

FIG. 6 is a cross-sectional view illustrating a semiconductor package according to some example implementations of the present disclosure.

Referring to FIG. 6, a semiconductor package 4000 of the example implementations may have the features identical to or similar to those described with reference to FIGS. 1-3, except that the lower semiconductor chip 130 is spaced apart from the upper semiconductor chip 230 in a direction (e.g., in the Z-axis direction), perpendicular to the upper surface of the lower semiconductor chip 130, and a portion of the encapsulant 150 is disposed between the lower semiconductor chip 130 and the upper semiconductor chip 230. Accordingly, the description of the semiconductor package 1000 illustrated in FIGS. 1-3 may be combined with the description of the semiconductor package 4000 according to these example implementations, unless otherwise specifically stated.

A portion of the encapsulant 150 of the semiconductor package 4000 of some example implementations may be disposed between the lower semiconductor chip 130 and the upper semiconductor chip 230.

The encapsulant 150 may include an intermediate interposed portion 150INM interposed between the lower semiconductor chip 130 and the upper semiconductor chip 230. The intermediate interposed portion 150INM may separate the lower semiconductor chip 130 from the upper semiconductor chip 230 in a direction (e.g., the Z-axis direction) perpendicular to the upper surface of the lower semiconductor chip 130. The intermediate interposed portion 150INM may be disposed between the lower semiconductor chip 130 and the upper semiconductor chip 230.

For the convenience of explanation, the intermediate interposed portion 150INM of the encapsulant 150 is described separately, but the intermediate interposed portion 150INM of the encapsulant 150 may have an integral structure connected to the encapsulant 150 without a boundary. The intermediate interposed portion 150INM may include the same material as the encapsulant 150.

The intermediate interposed portion 150INM may be interposed between the lower semiconductor chip 130 and the upper semiconductor chip 230 and may be in contact with the upper surface of the lower semiconductor chip 130 and the lower surface of the upper semiconductor chip 230.

The intermediate interposed portion 150INM may bond and couple the lower semiconductor chip 130 and the upper semiconductor chip 230 to each other. The upper surface of the lower semiconductor chip 130 may be bonded to the lower surface of the intermediate interposed portion 150INM, and the lower surface of the upper semiconductor chip 230 may be bonded to the upper surface of the intermediate interposed portion 150INM.

A process of disposing the inter-chip adhesive layer 180 on the lower semiconductor chip 130 and bonding the inter-chip adhesive layer 180 to the upper semiconductor chip 230 and a process of arranging the encapsulant 150 may be integrated into a single process omitting the inter-chip adhesive layer 180, so that the manufacturing process may be simplified. Accordingly, the overall production time and the number of processes may be reduced, and the number of processes may be reduced, thus reducing the equipment operating costs and labor costs. Accordingly, the overall efficiency and economy of the production of the semiconductor package 4000 may be improved.

The encapsulant 150 may be disposed between the lower semiconductor chip 130 and the upper semiconductor chip 230, thus effectively dispersing the stress caused by a difference in the coefficient of thermal expansion (CTE) between the lower semiconductor chip 130, the upper semiconductor chip 230 and the encapsulant 150. Accordingly, cracking or peeling may be prevented even in a repetitive temperature change cycle test (e.g., a TC Test or a Thermal Cycle Test) environment. For example, reliability may be secured when used in automotive electronic devices or server chips that are subjected to repeated high temperatures. Accordingly, a high-reliability semiconductor package 4000 that is resistant to heat cycles may be implemented.

FIG. 7 is a cross-sectional view illustrating a semiconductor package according to some example implementations of the present disclosure.

Referring to FIG. 7, the semiconductor package 5000 of the example implementations may have the features identical to or similar to those described with reference to FIGS. 1-3, except that the first length L1 and the second length L2 are substantially the same. Accordingly, the description of the semiconductor package 1000 illustrated in FIGS. 1-3 may be combined with the description of the semiconductor package 5000 according to these example implementations, unless otherwise specifically stated.

The plurality of first through-structures 141 may have a first length L1 in the vertical direction (e.g., the Z-axis direction). The plurality of second through-structures 142 may have a second length L2 in the vertical direction (e.g., the Z-axis direction). The first length L1 may be substantially the same as the second length L2.

When the first length L1 and the second length L2 are equal to each other, structural balance between the lower interconnection structure 110 and the upper interconnection structure 120 may be secured, so that thermal or mechanical loads may be evenly distributed. Accordingly, the possibility of deformation or cracking due to a difference in the coefficient of thermal expansion (CTE) may be reduced, thereby improving the long-term reliability and durability of the semiconductor package 5000.

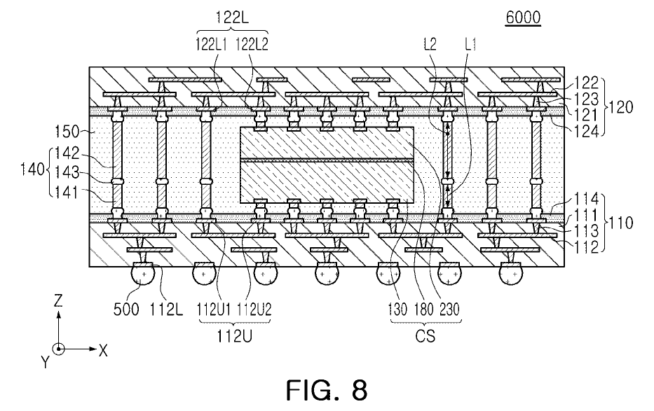

FIG. 8 is a cross-sectional view illustrating a semiconductor package According to some example implementations of the present disclosure.

Referring to FIG. 8, a semiconductor package 6000 of the example implementations may have the features identical to or similar to those described with reference to FIGS. 1-3, except that the first length L1 is less than the second length L2. Accordingly, the description of the semiconductor package 1000 illustrated in FIGS. 1-3 may be combined with the description of the semiconductor package 6000 according to these example implementations, unless otherwise specifically stated.

The plurality of first through-structures 141 may have a first length L1 in a vertical direction (e.g., in the Z-axis direction). The plurality of second through-structures 142 may have a second length L2 in the vertical direction (e.g., the Z-axis direction). The first length L1 may be less than the second length L2.

When the semiconductor package 6000 is formed by setting the first length L1 to be less than the second length L2, it may be advantageous in terms of space utilization when disposing the first through-structures 141 on the lower interconnection structure 110. For example, the degree of freedom in designing an interconnection pattern or an electrode required on the upper surface of the lower interconnection structure 110 may increase. Layout restrictions may be reduced when designing a highly integrated circuit within the lower interconnection structure 110. In addition, the semiconductor package 6000 may also contribute to minimizing electrical interference or interference paths. Accordingly, the design flexibility and performance optimization of the semiconductor package 6000 may be secured.

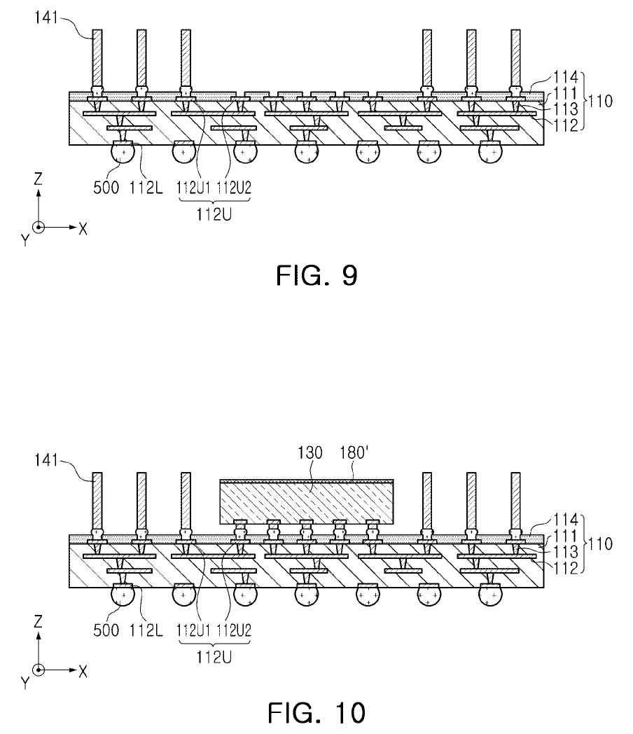

FIGS. 9-14 are cross-sectional views schematically illustrating a manufacturing process of a semiconductor package according to some example implementations of the present disclosure.

Referring to FIG. 9, a lower interconnection structure 110 may be prepared, and a plurality of first through-structures 141 may be formed on the lower interconnection structure 110.

The lower interconnection structure 110 may be prepared. The lower interconnection structure 110 may include a lower insulating layer 111, a lower interconnection layer 112 disposed within the lower insulating layer 111, a lower interconnection via 113 connecting the lower interconnection layers 112 disposed on different levels, and a lower protection layer 114 disposed on the upper surface of the lower insulation layer 111.

An opening may be formed in the lower protection layer 114 to expose at least a portion of the lower connection terminals 112U from the lower protection layer 114. The openings may be formed by a process of etching a portion of the lower protection layer 114. The openings may expose at least a portion of the lower connection terminals 112U and may be narrower than a width of the lower connection terminals 112U in the first direction (e.g., in the X-axis direction), but the present disclose is not limited thereto.

A plurality of first through-structures 141 may be formed on the lower interconnection structure 110. The plurality of first through-structures 141 may include a metallic material, and in some example implementations, the plurality of first through-structures 141 may include copper (Cu), but the present disclosure is not limited thereto. The plurality of first through-structures 141 may be connected to the lower interconnection structure 110 through the first solder portions 141S (see FIG. 3) respectively disposed on lower sides thereof. Specifically, the plurality of first through-structures 141 may be connected to first upper connection terminals 112U1 through the first solder portions 141S (see FIG. 3).

Referring to FIG. 10, a lower semiconductor chip 130 in which a preliminary inter-chip adhesive layer 180’ is applied to an upper surface thereof may be mounted on the lower interconnection structure 110.

The preliminary inter-chip adhesive layer 180’ may be applied to the upper surface of the lower semiconductor chip 130. The preliminary inter-chip adhesive layer 180’ may include at least one of materials that may be bonded and coupled to each other, for example, silicon oxide (SiO) and compounds thereof. In some example implementations, the preliminary inter-chip adhesive layer 180’ may include a thermosetting resin or an ultraviolet-curable resin in a film form. For example, the preliminary inter-chip adhesive layer 180’ may include a resin film such as a die attach film (DAF). The lower semiconductor chip 130 may be mounted on the lower interconnection structure 110.

The lower semiconductor chip 130 may be electrically connected to the second lower connection terminals 112U2 through conductive bumps 135. The second lower connection terminals 112U2 are lower connection terminals adjacent to the center of the lower connection terminals 112U and may be electrically connected to the lower interconnection layer 112 through the lower interconnection via 113. The conductive bumps 135 may include a pillar portion 133 and a solder portion 134, and referring to FIG. 9, the solder portion 134 may fill the opening of the lower protection layer 114 and may be in contact with at least a portion of the lower protection layer 114.

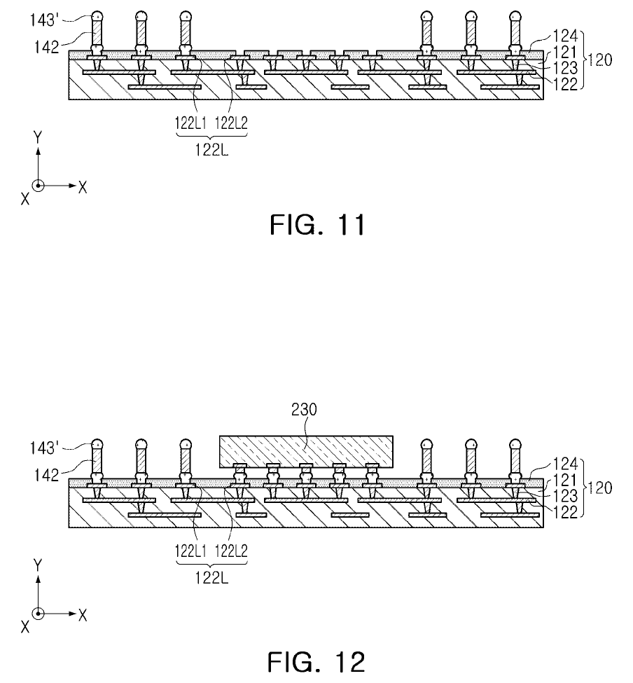

Referring to FIG. 11, an upper interconnection structure 120 may be prepared, and a plurality of second through-structures 142 may be formed on the upper interconnection structure 120.

The upper interconnection structure 120 may be prepared. The upper interconnection structure 120 may include an upper insulating layer 121, an upper interconnection layer 122 disposed within the upper insulating layer 121, an upper interconnection via 123 connecting the upper interconnection layers 122 disposed on different levels, and an upper protection layer 124 disposed on an upper surface of the upper insulating layer 121.

An opening may be formed in the upper protection layer 124 to expose at least a portion of the upper connection terminals 122L from the upper protection layer 124. The openings may be formed by a process of etching a partial region of the upper protection layer 124. The openings may expose at least a portion of the upper connection terminals 122L and may be narrower than a width of the upper connection terminals 122L in the first direction (e.g., X-axis direction), but the present disclosure is not limited thereto.

A plurality of second through-structures 142 may be formed on the upper interconnection structure 120. The plurality of second through-structures 142 may include a metallic material, and in some example implementations, the plurality of second through-structures 142 may include copper (Cu), but the present disclosure is not limited thereto. The plurality of second through-structures 142 may be connected to the upper interconnection structure 120 through second solder portions 142S disposed on respective lower portions thereof. Specifically, the plurality of second through-structures 142 may be connected to the first upper connection terminals 122L1 through the second solder portions 142S, respectively.

A plurality of preliminary connection members 143’ may be formed on the plurality of second through-structures 142. The plurality of preliminary connection members 143’ may be formed on the second through-structure 142. A lower surface of the preliminary connection members 143’ may be in contact with an upper surface of the second through-structure 142. The plurality of preliminary connection members 143’ may include a low melting point metal, for example, tin (Sn) or alloys including tin (Sn). An upper side of the second through-structure 142 may contact a lower side of the preliminary connection members 143’. The preliminary connection members 143’ may be electrically connected to the second through-structure 142.

Referring to FIG. 12, an upper semiconductor chip 230 may be mounted on the upper interconnection structure 120.

The upper semiconductor chip 230 may be mounted on the upper interconnection structure 120. The upper semiconductor chip 230 may be electrically connected to the second lower connection terminals 122L2 through conductive bumps 235 (see FIG. 3). The second upper connection terminals 122L2 are upper connection terminals adjacent to a center of the upper connection terminals 112L and may be electrically connected to the upper interconnection layer 122 through the upper interconnection via 123. The conductive bumps 235 (see FIG. 3) may include the pillar portion 233 (see FIG. 3) and the solder portion 234 (see FIG. 3), and referring to FIG. 12, the solder portion 234 (see FIG. 3) may fill an opening in the upper protection layer 124 and may be in contact with at least a portion of the upper protection layer 124.

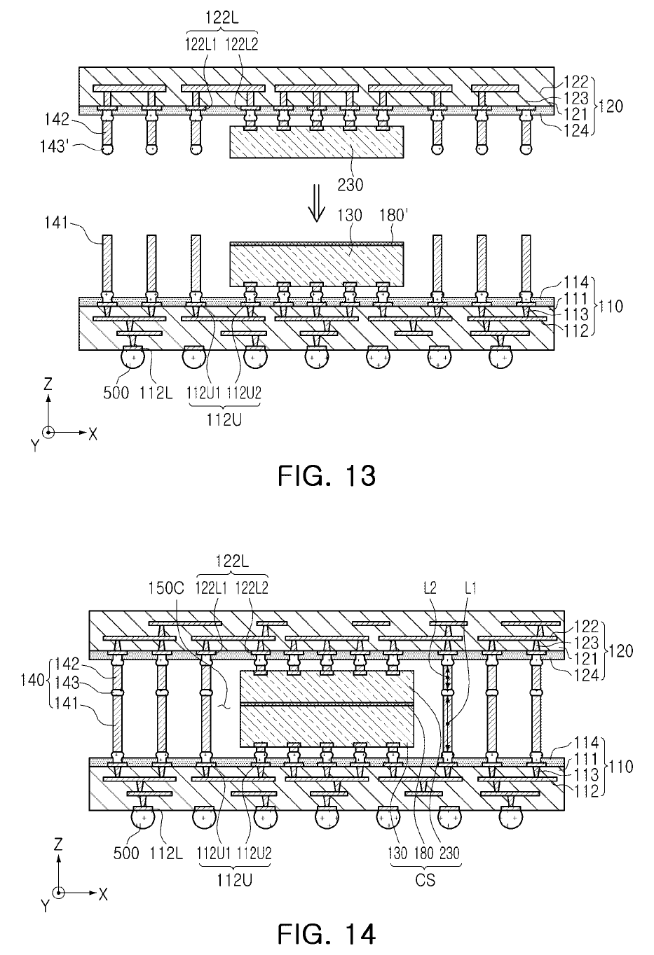

Referring to FIG. 13, the upper interconnection structure 120 and the plurality of second through-structures 142 may be bonded to the lower interconnection structure 110 and the plurality of first through-structures 141 through the preliminary connection member 143’.

The plurality of second through-structures 142 of the upper interconnection structure 120 and the plurality of first through-structures 141 of the lower interconnection structure 110 may be disposed to face each other. For example, an upper semiconductor chip 230 of the upper interconnection structure 120 may be disposed to face a lower semiconductor chip 130 of the lower interconnection structure 110. For example, the upper interconnection structure 120 may be rotated 180 degrees with respect to a horizontal axis (e.g., X-axis or Y-axis). As the plurality of second through-structures 142 of the upper interconnection structure 120 and the plurality of first through-structures 141 of the lower interconnection structure 110 are disposed to face each other, the description with respect to FIG. 13 of upper surfaces and lower surfaces of each of the upper interconnection structure 120, the plurality of second through-structures 142 and the plurality of preliminary connection members 143’ may change from how they are described in FIG. 12 so that upper surfaces of each of the upper interconnection structure 120, the plurality of second through-structures 142 and the plurality of spare connection members 143’ may correspond to lower surfaces in FIG. 13.

The upper interconnection structure 120 and the lower interconnection structure 110 may be coupled to each other.

The lower surface of the upper semiconductor chip 230 and the upper surface of the preliminary inter-chip adhesive layer 180’ may be bonded to each other. The inter-chip adhesive layer 180 may bond and couple the lower semiconductor chip 130 and the upper semiconductor chip 230 to each other. The upper surface of the lower semiconductor chip 130 may be bonded to the lower surface of the inter-chip adhesive layer 180, and the lower surface of the upper semiconductor chip 230 may be bonded to the upper surface of the inter-chip adhesive layer 180.

The lower surfaces of the plurality of preliminary connection members 143’ and the upper surfaces of the plurality of first through-structures 141 may be bonded to each other. The plurality of connection members 143 may be disposed between the plurality of first through-structures 141 and the plurality of second through-structures 142. The lower surface of the connection member 143 may be in contact with an upper surface of the first through-structure 141, and the upper surface of the connection member 143 may be in contact with a lower surface of the second through-structure 142. Each of the plurality of first through-structures 141 may be electrically connected to a respective second through-structure of the plurality of second through-structures 142 through the connection member 143 disposed on an upper side of the first through-structure 141. The first through-structure 141 may be electrically connected to the upper interconnection layer 122 through the connection member 143 and the second through-structure 142.

Each of the plurality of second through-structures 142 may be electrically connected to a respective first through-structure of the plurality of first through-structures 141 through the connection member 143 disposed on a lower side of the second through-structure 142. The second through-structure 142 may be electrically connected to the lower interconnection layer 112 through the connection member 143 and the first through-structure 141. The connection member 143 may be electrically connected to the first through-structure 141. The connection member 143 may be electrically connected to the second through-structure 142. The first through-structure 141 and the second through-structure 142 may be electrically connected through the connection member 143.

Referring to FIGS. 14 and 1, an encapsulant 150 may be filled in a space 150C between the upper interconnection structure 120 and the lower interconnection structure 110.

The encapsulant 150 may be filled in the space 150C between the upper interconnection structure 120 and the lower interconnection structure 110 to cover the chip structure CS and the plurality of through-structures 140. The encapsulant 150 may encapsulate at least portions of each of the lower semiconductor chip 130, the inter-chip adhesive layer 180, the upper semiconductor chip 230, the first through-structure 141 and the second through-structure 142 so as to fill the space 150C between the upper interconnection structure 120 and the lower interconnection structure 110. The encapsulant 150 may be formed to cover side surfaces of each of the plurality of first and second through-structures 141 and 142. The encapsulant 150 may be formed on the lower interconnection structure 110 to cover at least portions of the chip structure CS and the plurality of through-structures 140.

An upper interposed portion 150INU surrounding each of the upper conductive bumps 235 between the upper surface of the chip structure CS and the upper interconnection structure 120 may be formed. The upper interposed portion 150INU may be interposed between the upper semiconductor chip 230 and the upper interconnection structure 120 and may thus be in contact with the lower surface of the upper interconnection structure 120 and the upper surface of the upper semiconductor chip 230. Each of the upper conductive bumps 235 may be surrounded by the encapsulant 150, and in this case, a Molded Underfill (MUF) in which the encapsulant 150 fills a periphery of the upper conductive bumps 235 structure may be formed. The upper interposed portion 150INU may be interposed between the upper semiconductor chip 230 and the upper interconnection structure 120 and may thus be in contact with the lower surface of the upper interconnection structure 120 and the upper surface of the upper semiconductor chip 230. A sidewall of the upper interposed portion 150INU may be in contact with sidewalls of the upper conductive bumps 235.

A lower interposed portion 150INL may be formed to surround each of the lower conductive bumps 135 between the lower surface of the chip structure CS and the lower interconnection structure 110. The lower interposed portion 150INL may be interposed between the lower semiconductor chip 130 and the lower interconnection structure 110 and may thus be in contact with the upper surface of the lower interconnection structure 110 and the lower surface of the lower semiconductor chip 130. Each of the lower conductive bumps 135 may be surrounded by the encapsulant 150, and in this case, a Molded Underfill (MUF) structure in which the encapsulant 150 fills a periphery of the lower conductive bumps 135 may be formed. The lower interposed portion 150INL may be interposed between the lower semiconductor chip 130 and the lower interconnection structure 110 and may thus be in contact with the upper surface of the lower interconnection structure 110 and the lower surface of the lower semiconductor chip 130. A sidewall of the lower interposed portion 150INL may be in contact with sidewalls of the lower conductive bumps 135.

A method for manufacturing a semiconductor package according to example implementations may comprise: preparing a lower interconnection structure, the lower interconnection structure including a lower insulating layer and a lower interconnection layer disposed within the lower insulating layer; disposing a first through-structure on the lower interconnection structure; preparing an upper interconnection structure, the upper interconnection structure including an upper insulating layer and an upper interconnection layer disposed within the upper insulating layer; disposing a second through-structure on the upper interconnection structure; and disposing the upper interconnection structure on the lower interconnection structure so that the first through-structure and the second through-structure face each other.

Also, the method may further comprise the lower interconnection layer may comprise a lower connection terminal, a pad portion of an uppermost lower interconnection layer, and the first through-structure may comprise a first solder portion disposed on a surface of the first through-structure facing the lower interconnection structure, and the disposing the first through-structure on the lower interconnection structure may comprise bonding the first solder portion on the lower connection terminal.

Also, the method may further comprise the upper interconnection layer may comprise an upper connection terminal, a pad portion of an uppermost upper interconnection layer, and the second through-structure may comprise a second solder portion disposed on a surface of the second through-structure facing the upper interconnection structure, and disposing the second through-structure on the upper interconnection structure may comprise bonding the second solder portion on the upper connection terminal.

Also, the method may further comprise disposing the upper interconnection structure on the lower interconnection structure so that the first through-structure and the second through-structure face each other may comprise disposing the upper interconnection structure and the lower interconnection structure to be electrically connected to each other.

Also, the method may further comprise the upper interconnection structure may comprise a preliminary connection member disposed on an upper side of the second through-structure, and electrically connecting the upper interconnection structure and the lower interconnection structure to each other may comprise bringing the preliminary connection member into contact with an upper side of the first through-structure.

Also, the method may further comprise the lower interconnection structure may further comprise a lower protection layer on the lower interconnection layer, and the method may comprise forming an opening in the lower protection layer to expose a portion of the lower interconnection layer and disposing the first through-structure on the exposed portion of the lower interconnection layer.

Also, the method may further comprise the upper interconnection structure may comprise an upper protection layer on the upper interconnection layer, and the method may comprise forming an opening in the upper protection layer to expose a portion of the upper interconnection layer and disposing the second through-structure on the exposed portion of the upper interconnection layer.

Also, the method may further comprise the preparing the lower interconnection structure may further comprise mounting a lower semiconductor chip on the lower interconnection structure.

Also, the method may further comprise the preparing the upper interconnection structure may further comprise mounting an upper semiconductor chip on the upper interconnection structure.

Also, the method may further comprise after disposing the upper interconnection structure on the lower interconnection structure so that the first through-structure and the second through-structure face each other, the method may further comprise forming an encapsulant to fill a space between the lower interconnection structure and the upper interconnection structure.

The example implementations described above and the attached drawings do not limit the present disclosure, and the present disclosure is intended to be limited by the attached claims. Meanwhile, those skilled in the art will be able to make various substitutions, modifications, changes, and combinations of the example implementations within the scope that does not depart from the technical idea of the present disclosure described in the claims. It should also be understood that modifications and combinations of forms that may be approved are also within the scope of the present disclosure.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Therefore, various forms of substitution, modification, and change and combinations of example implementations may be possible by those skilled in the art within the scope that does not depart from the technical idea of the present disclosure described in the claims, and this will also be considered to fall within the scope of the present disclosure.

What is claimed is:

1. A semiconductor package, comprising:
a lower interconnection structure;
a chip structure on the lower interconnection structure;
a plurality of through-structures around the chip structure and on the lower interconnection structure;
an encapsulant covering at least portions of the chip structure and at least portions of the plurality of through-structures, wherein the encapsulant is on the lower interconnection structure; and
an upper interconnection structure on the encapsulant,
wherein the lower interconnection structure comprises
a lower insulating layer, and
a lower interconnection layer within the lower insulating layer,
the upper interconnection structure comprises
an upper insulating layer, and
an upper interconnection layer within the upper insulating layer,
the chip structure comprises
a lower semiconductor chip on the lower interconnection structure and electrically connected to the lower interconnection layer, and
an upper semiconductor chip on the lower semiconductor chip and electrically connected to the upper interconnection layer, and
each of the plurality of through-structures comprises
a first through-structure around the lower semiconductor chip and on the lower interconnection structure,
a second through-structure around the upper semiconductor chip and on the first through-structure, and
connection members between the first through-structure and the second through-structure, wherein the connection members bond the first through-structure and the second through-structure to each other.

2. The semiconductor package of claim 1, wherein the first through-structure is electrically connected to the lower interconnection layer, and
the second through-structure is electrically connected to the upper interconnection layer.

3. The semiconductor package of claim 1, wherein the lower interconnection layer comprises
a plurality of lower interconnection layers on different levels, and
lower interconnection vias electrically connecting the plurality of lower interconnection layers,
wherein the upper interconnection layer comprises
a plurality of upper interconnection layers on different levels, and
upper interconnection vias electrically connecting the plurality of upper interconnection layers,
the first through-structure is electrically connected to the lower semiconductor chip through the lower interconnection vias and the lower interconnection layers, and
the second through-structure is electrically connected to the upper semiconductor chip through the upper interconnection vias and the upper interconnection layer.

4. The semiconductor package of claim 1, wherein in a direction parallel to an upper surface of the lower interconnection structure,
a width of a lower side of the first through-structure and a width of an upper side of the first through-structure are substantially the same,
a width of a lower side of the second through-structure and a width of an upper side of the second through-structure are substantially the same, and
the width of the upper side of the first through-structure and the width of the lower side of the second through-structure are substantially the same.

5. The semiconductor package of claim 1, wherein, in a direction perpendicular to an upper surface of the lower interconnection structure, a thickness of the upper semiconductor chip is less than a thickness of the lower semiconductor chip.

6. The semiconductor package of claim 1, comprising:
an inter-chip adhesive layer between the lower semiconductor chip and the upper semiconductor chip,
wherein an upper surface of the lower semiconductor chip is bonded to a lower surface of the inter-chip adhesive layer, and
a lower surface of the upper semiconductor chip is bonded to an upper surface of the inter-chip adhesive layer.

7. The semiconductor package of claim 1, wherein the lower semiconductor chip is spaced apart from the upper semiconductor chip in a direction perpendicular to an upper surface of the lower semiconductor chip, and
a portion of the encapsulant is between the lower semiconductor chip and the upper semiconductor chip.

8. A semiconductor package, comprising:
a lower interconnection structure comprising a lower insulating layer and lower connection terminals on an upper surface of the lower insulating layer;
a lower semiconductor chip on the lower interconnection structure;
a first through-structure around the lower semiconductor chip and on the lower interconnection structure;
a second through-structure on the first through-structure;
a connection member between the first through-structure and the second through-structure and electrically connecting the first through-structure and the second through-structure;
an upper interconnection structure on the second through-structure and comprising an upper insulating layer and upper connection terminals on a lower surface of the upper insulating layer;
an upper semiconductor chip between the upper interconnection structure and the lower semiconductor chip; and
an encapsulant between the lower interconnection structure and the upper interconnection structure and covering at least a portion of each of the lower semiconductor chip, the upper semiconductor chip, the first through-structure, and the second through-structure,
wherein the lower connection terminals comprise a first lower connection terminal electrically connected to the first through-structure and a second lower connection terminal electrically connected to the lower semiconductor chip, and
the upper connection terminals comprise a first upper connection terminal electrically connected to the second through-structure and a second upper connection terminal electrically connected to the upper semiconductor chip.

9. The semiconductor package of claim 8, wherein the encapsulant comprises:
a lower interposed portion between the lower semiconductor chip and the lower interconnection structure, wherein the lower interposed portion contacts an upper surface of the lower interconnection structure and a lower surface of the lower semiconductor chip; and
an upper interposed portion between the upper semiconductor chip and the upper interconnection structure, wherein the upper interposed portion contacts a lower surface of the upper interconnection structure and an upper surface of the upper semiconductor chip.

10. The semiconductor package of claim 9, comprising:
lower conductive bumps between the lower semiconductor chip and the second lower connection terminal; and
upper conductive bumps between the upper semiconductor chip and the second upper connection terminal,
wherein sidewalls of the lower interposed portion and the upper interposed portion are in contact with sidewalls of the lower conductive bumps and the upper conductive bumps, respectively.

11. The semiconductor package of claim 10, wherein the lower interconnection structure comprises
a lower interconnection layer within the lower insulating layer, and
lower interconnection vias connecting the lower interconnection layer and the lower connection terminals, and
wherein the upper interconnection structure comprises
an upper interconnection layer within the upper insulating layer, and
upper interconnection vias connecting the upper interconnection layer and the upper connection terminals.

12. The semiconductor package of claim 11, comprising:
a first solder portion on a lower side of the first through-structure,
wherein the first through-structure is electrically connected to the lower interconnection layer through the first solder portion and the first lower connection terminal.

13. The semiconductor package of claim 11, comprising:
a second solder portion on an upper side of the second through-structure,
wherein the second through-structure is electrically connected to the upper interconnection layer through the second solder portion and the first upper connection terminal.

14. The semiconductor package of claim 11, wherein the lower semiconductor chip is electrically connected to the first through-structure through the lower connection terminals, the lower interconnection vias and the lower interconnection layer, and
the upper semiconductor chip is electrically connected to the second through-structure through the upper connection terminals, the upper interconnection vias and the upper interconnection layer, and
the lower semiconductor chip and the upper semiconductor chip are electrically connected to each other.

15. The semiconductor package of claim 8, wherein with reference to an upper surface of the lower interconnection structure, a level on which the first lower connection terminal is disposed is substantially the same as a level on which the second lower connection terminal is disposed, and
a level on which the first upper connection terminal is disposed is lower than a level on which the second upper connection terminal is disposed.

16. A semiconductor package, comprising:
a lower interconnection structure comprising a lower insulating layer and a lower interconnection layer;
a lower semiconductor chip mounted on the lower interconnection structure and electrically connected to the lower interconnection layer;
a first through-structure around the lower semiconductor chip, on the lower interconnection structure;
an upper semiconductor chip mounted on the lower semiconductor chip;
a second through-structure around the upper semiconductor chip, on the first through-structure;
an encapsulant encapsulating the lower semiconductor chip, the first through-structure, the upper semiconductor chip and the second through-structure, on the lower interconnection structure; and
an upper interconnection structure on the encapsulant and including an upper insulating layer and an upper interconnection layer electrically connected to the upper semiconductor chip,
wherein an upper side of the first through-structure and a lower side of the second through-structure face each other, and
the first through-structure and the second through-structure are electrically connected to each other through the upper side of the first through-structure and the lower side of the second through-structure.

17. The semiconductor package of claim 16, wherein the first through-structure has a first length in a first direction perpendicular to an upper surface of the lower interconnection structure,
the second through-structure has a second length in the first direction, and
the first length is substantially the same as the second length.

18. The semiconductor package of claim 16, wherein the first through-structure has a first length in a first direction perpendicular to an upper surface of the lower interconnection structure,
the second through-structure has a second length in the first direction, and
the first length is less than the second length.

19. The semiconductor package of claim 16, comprising:
a connection member between the first through-structure and the second through-structure,
wherein, in a direction parallel to an upper surface of the lower interconnection structure, a width of an upper side of the first through-structure is substantially the same as a width of a lower side of the second through-structure, and
a width of the connection member is greater than the width of the upper side of the first through-structure.

20. The semiconductor package of claim 16, wherein the lower interconnection layer comprises
a plurality of lower interconnection layers on different levels, in a first direction perpendicular to an upper surface of the lower interconnection structure, and
lower interconnection vias electrically connecting the plurality of lower interconnection layers, and
the upper interconnection layer comprises
a plurality of upper interconnection layers on different levels, in the first direction, and
upper interconnection vias electrically connecting the plurality of upper interconnection layers,
a width of lower sides of the upper interconnection vias is greater than a width of upper sides thereof, in a second direction parallel to the upper surface of the lower interconnection structure, and
in the second direction, a width of lower sides of the lower interconnection vias is smaller than a width of upper sides thereof.
